(19) United States
(12) Patent Application Publication
(10) Pub. No.: US 2021/0396693 A1
(43) Pub. Date: Dec. 23, 2021

(54) SENSOR ELEMENT, MEASUREMENT DEVICE, AND MEASUREMENT METHOD

(71) Applicant: KYOTO UNIVERSITY, Kyoto-shi, Kyoto (JP)

(72) Inventors: Norikazu MIZUOCHI, Kyoto-shi, Kyoto (JP); Hiroki MORISHITA, Kyoto-shi, Kyoto (JP); Toshiyuki TASHIMA, Kyoto-shi, Kyoto (JP)

(21) Appl. No.: 17/281,636

(22) PCT Filed: Oct. 1, 2019
(86) PCT No.: PCT/JP2019/038794

§ 371 Date: Mar. 31, 2021

(30) Foreign Application Priority Data
Oct. 2, 2018 (JP) 2018-187611

(51) Int. Cl. G01N 24/10; G01R 33/60; G06N 10/00

(52) U.S. Cl. CPC G01N 24/10; G06N 10/00; G01R 33/60

(57) ABSTRACT

In order to improve the measurement sensitivity in measurement using a color center as a sensor, a sensor element (1) has a color center in a diamond crystal structure, wherein the electron spin state of the color center is a dressed state.

### TECHNICAL FIELD

The present invention relates to a sensor element, a measurement device, and a measurement method, all of which use color centers as sensors.

### BACKGROUND ART

Composite defects called “nitrogen-vacancy centers” are sometimes observed in the crystal structure of diamond. Nitrogen-vacancy centers have a pair of a nitrogen atom replacing the position of a carbon atom in the crystal lattice and a vacancy present in the position adjacent to the nitrogen atom (a carbon atom is missing), and are also called “NV centers.” In addition to NV centers, composite defects called “silicon-vacancy centers” and “germanium-vacancy centers” are also sometimes observed in the crystal structure of diamond. These composite defects, including NV centers, are called “color centers.”

NV centers show magnetic properties called “electron spin” in a state in which electrons are trapped in vacancies (a negative charge state, hereinafter referred to as “NV⁻”). NV⁻ shows a longer transverse relaxation time (decoherence time, hereinafter referred to as “T₂”) compared with a state in which electrons are not trapped (a neutral state, hereinafter referred to as “NV⁰”). That is, in the NV⁻ electron spin state, after the magnetization of the electron spins aligned in the perpendicular direction of the external magnetic field (hereinafter referred to as “quantization axis”) is tilted in the transverse direction, the individual directions are shifted due to the precessional motion of the individual spins, and it takes a long time for the transverse magnetization as a whole to disappear. Further, NV⁻ also shows a long T₂ value even at room temperature (about 300 K).

The NV⁻ electron spin state changes in response to the external magnetic field, and this electron spin state can be measured at room temperature. Therefore, diamond containing NV centers can be used as a material for magnetic field sensor elements.

Furthermore, the NV⁻ electron spin state can also be artificially operated (placed in a specific electron spin state) from the outside by a method such as electromagnetic wave irradiation. Since this operation is also possible at room temperature, NV centers are expected, also due to their long T₂, to be available as qubits that can stably write and read the quantum state. Diamond with color centers, such as NV centers, is expected to be used as a material for quantum information devices and electronic circuit devices.

For example, PTL 1 discloses a sensor using diamond with color centers.

### CITATION LIST

### Patent Literature

PTL 1: JP2017-514130A

### SUMMARY OF INVENTION

### Technical Problem

In the measurement of magnetic fields etc. using color centers in diamond as sensors, further improvement has been required for measurement sensitivity.

As an example, a case of measuring a magnetic field is explained. The detection sensitivity of magnetic field measurement by a sensor using color centers in diamond is represented by the following equation:

Bₘᵢₙ∝1/\sqrt{NT₂}

In this equation, Bₘᵢₙ is the minimum detectable strength of the magnetic field, and N is the number of qubits. When the decoherence time T₂ increases, the minimum detectable strength Bₘᵢₙ of the magnetic field decreases; thus, in order to further improve the measurement sensitivity, it is required to further increase the decoherence time.

An object of the present invention is to improve the measurement sensitivity in measurement using a color center as a sensor.

### Solution to Problem

The present invention for achieving the above object includes, for example, the embodiments shown below.

Item 1.

A sensor element having a color center in a diamond crystal structure, wherein the electron spin state of the color center is a dressed state.

Item 2.

The sensor element according to Item 1, wherein the color center is a diamond complex containing nitrogen (N) replacing one carbon atom and a vacancy (V) adjacent to the nitrogen.

Item 3.

A measurement device comprising:

an irradiation unit that irradiates a sensor element having a color center with driving microwaves for generating a dressed state in the electron spin state of the color center that changes due to interaction with a measurement target, and with operation electromagnetic waves for operating the electron spin state; and

a physical quantity measuring unit that calculates a physical quantity of the measurement target based on the electron spin dressed state after the interaction with the measurement target.

Item 4.

The measurement device according to Item 3, wherein the physical quantity measuring unit comprises:

a quantum circuit part that performs a quantum operation on phase information between multiple energy levels for the electron spin dressed state after the interaction with the measurement target;

a light irradiation part that irradiates the sensor element with light for reading the phase information after the quantum operation;

a detection part that detects a change generated in the sensor element due to the irradiation of the light; and

a data processing part that reads the phase information after the quantum operation from the detected change and calculates the physical quantity based on the read phase information.

Item 5.

The measurement device according to Item 4, wherein the quantum circuit part comprises:

a plurality of Hadamard action parts that act on the respective multiple energy levels; and

a plurality of unitary action parts that act on respective outputs of the plurality of Hadamard action parts and add the outputs to a quantum ancilla state.

Item 6.

The measurement device according to any one of Items 3 to 5, wherein the color center is a complex of nitrogen (N) replacing a carbon atom and a vacancy (V) adjacent to the nitrogen.

Item 7.

The measurement device according to any one of Items 3 to 6, wherein the physical quantity measuring unit calculates at least one of a magnetic field, an electric field, a temperature, and a dynamic quantity as the physical quantity related to interaction with the electron spin.

Item 8.

A measurement method comprising the steps of:

irradiating a sensor element having a color center with driving microwaves for generating a dressed state in the electron spin state of the color center that changes due to interaction with a measurement target;

irradiating the sensor element with operation electromagnetic waves for operating the electron spin state; and

calculating a physical quantity of the measurement target based on the electron spin dressed state after the interaction with the measurement target.

Item 9.

The measurement method according to Item 8, wherein the step of calculating the physical quantity comprises:

performing a quantum operation on phase information between multiple energy levels for the electron spin dressed state;

irradiating the sensor element with light for reading the phase information after the quantum operation;

detecting a change generated in the sensor element due to the irradiation of the light; and

reading the phase information after the quantum operation from the detected change and calculating the physical quantity based on the read phase information.

Item 10.

The measurement method according to Item 9, wherein the step of performing a quantum operation comprises:

allowing Hadamard gates to act on the respective multiple energy levels; and

allowing unitary operators to act on respective outputs of the Hadamard gates, and adding each of outputs of the unitary operators to a quantum ancilla state.

Item 11.

The measurement method according to any one of Items 8 to 10, wherein the step of applying operation electromagnetic waves comprises:

applying a π/2 pulse to thereby tilt an electron spin along a quantization axis to a plane perpendicular to the quantization axis;

applying a π pulse to thereby invert the electron spin dephased by the interaction with the measurement target in the plane; and

applying a π/2 pulse to thereby project the dephased electron spin onto the quantization axis.

Item 12.

The measurement method according to any one of Items 8 to 10, wherein the step of applying operation electromagnetic waves comprises:

applying a π/2 pulse to thereby tilt an electron spin along a quantization axis to a plane perpendicular to the quantization axis; and

applying a π/2 pulse to thereby project the electron spin dephased by the interaction with the measurement target onto the quantization axis.

### Advantageous Effects of Invention

The present invention can improve the measurement sensitivity in measurement using a color center as a sensor.

### BRIEF DESCRIPTION OF DRAWINGS

FIG. 1 is a view schematically showing an outline structure of a measurement device according to one embodiment of the present invention.

FIG. 2 is a view schematically showing changes in the energy levels of an electron spin in an NV center during a series of measurement procedures.

FIG. 3 is a view schematically showing the energy levels of an electron spin in an NV center before and after the generation of dressed states.

FIG. 4 is a view schematically showing a quantum circuit part that performs a quantum operation on dressed states.

FIG. 5 is a flowchart showing the procedure of a measurement method according to one embodiment of the present invention.

FIG. 6 is a flowchart showing the detailed procedure in the case of alternating magnetic field sensing.

FIG. 7 shows a pulse sequence for alternating magnetic field sensing.

FIG. 8 is a view schematically showing the behavior of an electron spin corresponding to the pulse sequence of FIG. 7.

FIG. 9 is a flowchart showing the detailed procedure of a quantum operation.

FIG. 10 is a flowchart showing the detailed procedure in the case of static magnetic field sensing.

FIG. 11 shows a pulse sequence for static magnetic field sensing.

FIG. 12 is a view schematically showing the behavior of an electron spin corresponding to the pulse sequence of FIG. 11.

FIG. 13 is a graph showing the results of measuring the decoherence time T₂ in Example 1.

FIG. 14 is a graph showing the results of measuring the decoherence time T₂* of a dressed electron spin in Example 2.

FIG. 15 is a graph showing the results of measuring the decoherence time T₂* of a bear electron spin.

FIG. 16 is a graph showing the correspondence relationship between the magnetic resonance signal intensity and the static magnetic field of a measurement target in Example 3.

### DESCRIPTION OF EMBODIMENTS

Embodiments of the present invention are described in detail below with reference to the attached drawings. In the following description and drawings, the same reference numerals indicate the same or similar components, and thus duplicate descriptions of the same or similar components are omitted.

In the present specification, “physical quantity” means a quantity whose dimensions are fixed under a certain system in physics and which can be expressed as a multiple of a defined physical unit. Examples of physical quantities include magnetic fields, electric fields, temperatures, and dynamic quantities (e.g., dynamic stress and pressure). Magnetic fields, electric fields, and dynamic quantities include physical quantities that do not change with time, and physical quantities that change direction repeatedly with time. That is, magnetic fields include a static magnetic field and an alternating magnetic field, electric fields include an electrostatic field and an alternating electric field, and dynamic quantities include a static dynamic quantity and an alternating dynamic quantity.

### First Embodiment

As an example of the physical quantities of a measurement target, the first embodiment of the present invention describes a case of measuring the strength of the alternating magnetic field generated from the measurement target.

### Device Structure

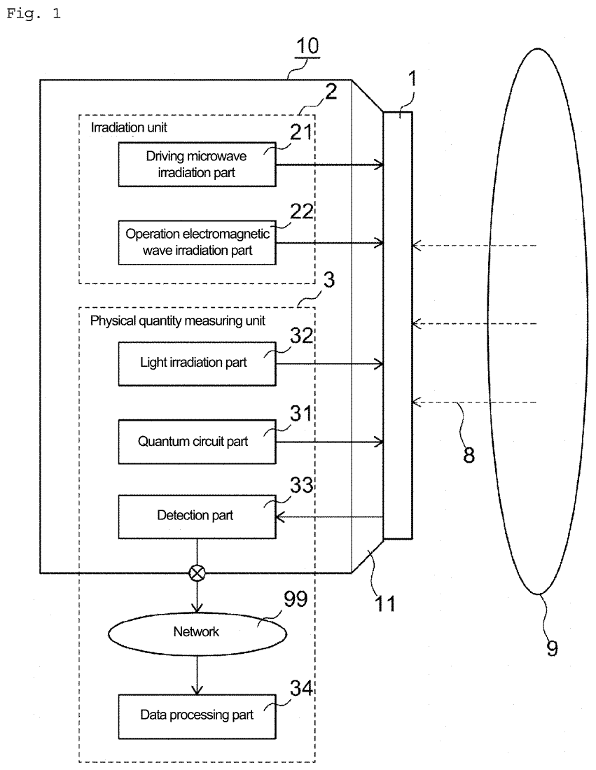

FIG. 1 schematically shows an outline structure of a measurement device 10 according to one embodiment of the present invention.

The measurement device 10 comprises a sensor element 1, an irradiation unit 2, and a physical quantity measuring unit 3. As an example, in the present embodiment, a confocal laser scanning microscope can be used to configure the measurement device 10.

In the present embodiment, the sensor element 1 is a diamond crystal having a color center, and an NV center is used as the color center. The NV center is a composite (composite defect) of nitrogen (N) replacing a carbon atom and a vacancy (V) adjacent to the nitrogen. In the present embodiment, the sensor element 1 is attached to the tip of a probe 11 of the measurement device 10.

The electron spin state of the color center of the sensor element 1 changes due to interaction 8 with the measurement target 9. In the present embodiment, the interaction 8 is interaction with an alternating magnetic field. When the interaction 8 is based on an alternating magnetic field, the electron spin state of the color center of the sensor element 1 corresponds to the strength of the alternating magnetic field generated from the measurement target 9.

The irradiation unit 2 comprises a driving microwave irradiation part 21 and an operation electromagnetic wave irradiation part 22. The driving microwave irradiation part 21 irradiates the sensor element 1 with driving microwaves for generating dressed states in the electron spin state of the color center. The details of the dressed state are described later. The operation electromagnetic wave irradiation part 22 irradiates the sensor element 1 with operation electromagnetic waves for operating the electron spin state of the color center. In the present embodiment, the driving microwaves are applied to the sensor element 1 in the form of continuous waves or pulsed waves, and the operation electromagnetic waves are applied to the sensor element 1 in the form of pulsed waves. Known microwave (MW) oscillators can be used as the driving microwave irradiation part 21 and the operation electromagnetic wave irradiation part 22.

The physical quantity measuring unit 3 calculates the physical quantity of the measurement target 9 based on the electron spin dressed state of the color center after the interaction with the measurement target 9. In the present embodiment, the physical quantity measuring unit 3 calculates the strength of the alternating magnetic field generated from the measurement target 9. The physical quantity measuring unit 3 comprises a quantum circuit part 31, a light irradiation part 32, a detection part 33, and a data processing part 34.

The quantum circuit part 31 performs a quantum operation on phase information between multiple energy levels for the electron spin dressed state after the interaction with the measurement target 9. As an example, the quantum circuit part 31 is realized by, for example, a magnetic resonance method using quantum gates by electromagnetic wave pulses. The details of the quantum operation are described later. The quantum circuit part 31 can be configured using a known microwave oscillator (pulse generator) and microwave switch. The microwave oscillator used to configure the quantum circuit part 31 and the microwave oscillator used to configure the irradiation unit 2 may be separate devices or may be integrated.

The light irradiation part 32 irradiates the sensor element 1 with light for reading the phase information after the quantum operation. Further, the light irradiation part 32 irradiates the sensor element 1 with light for initializing the electron spin state of the color center. For the light irradiation part 32, for example, various known laser generators can be used. As an optional structure, the light irradiation part 32 may comprise an acoustic optical modulator (AOM). The acoustic optical modulator can output the input laser light in pulsed form.

The detection part 33 detects a change generated in the sensor element 1. In the present embodiment, the detection part 33 detects the light emitted from the sensor element 1, thereby detecting the magnetic resonance signal as a change in luminescence intensity by known optically detected magnetic resonance (ODMR). In this case, for example, a known photodiode can be used as the detection part 33. The photodiode can be, for example, an avalanche photodiode.

In the present embodiment, the irradiation unit 2 applies the operation electromagnetic waves in pulsed form. Therefore, in the present embodiment, detection is specifically performed by pulsed optically detected magnetic resonance (pODMR).

The data processing part 34 is connected to the detection part 33, reads the phase information after the quantum operation from the change detected by the detection part 33, and calculates the physical quantity of the measurement target 9 based on the read phase information. In the present embodiment, the data processing part 34 calculates the strength of the alternating magnetic field generated from the measurement target 9. For the data processing part 34, for example, known general-purpose computers or various information terminal devices, such as smartphones, can be used. These information terminal devices are equipped with a processor for processing data. The data processing part 34 may be composed of an electronic circuit, instead of a processor.

The data processing part 34 may be integrated with the measurement device 10, or may be provided outside the measurement device 10 and connected to the measurement device 10 via a network 99, as shown in the drawing.

### Measurement Principle

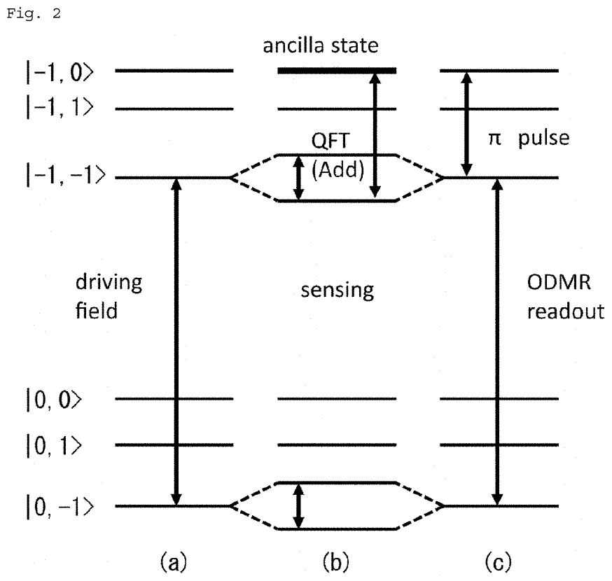

FIG. 2 is a view schematically showing changes in the energy levels of an electron spin in an NV center during a series of measurement procedures. In the drawing, the quantum state of the NV center is represented by |mₛ, m_{I}>. mₛ is the electron spin of the NV center, and m_{I} is the nuclear spin of nitrogen (¹⁴N).

In the present invention, dressed states |φ₁> and |φ₂> are generated in the electron spin state of the NV center, and the phases of the generated multiple dressed states |φ₁> and |φ₂> are added by a quantum operation and detected. Further, the generation of dressed states in the electron spin state of the NV center increases the decoherence time of the electron spin. The reason for the increased decoherence time is that the microwave mode is resistant to external noise. That is, the combination of the microwave mode and the NV center makes it more resistant to noise, including the NV center, and thus attenuation is less likely to occur. As a result, the decoherence time increases. In other words, due to the addition by the quantum operation and the increased decoherence time, the minimum detectable strength Bₘᵢₙ of the magnetic field is reduced, and the measurement sensitivity of the magnetic field is improved. In the present invention, in the measurement of the physical quantity, the measurement sensitivity is improved by using such a sensor element 1 in which the electron spin state of the color center is a dressed state.

A microwave dressed state is a new quantum state generated by combining the target system and the mode of microwaves applied to the target. The dressed state is a state in which the electron spin is dressed by microwaves. The generation of a microwave dressed state in the present invention is based on Autler-Townes splitting (ATS). The intensity, frequency, etc., of the driving microwaves applied to the sensor element 1 can be appropriately determined based on ATS.

FIG. 2(a) shows a state before the generation of dressed states. The ground state of the NV center is a spin triplet state, and the absorption of light excites the spin triplet ground state. In the steady state at room temperature, all levels are equally distributed in the ground state. In this state, when the NV center is photoexcited with laser light, the distribution probabilities of the levels are unevenly distributed, and the ground state of the NV center becomes a polarized state. The ground state of the NV center after laser light irradiation is expressed as |0, 0>, |0, 1>, and |0, −1>.

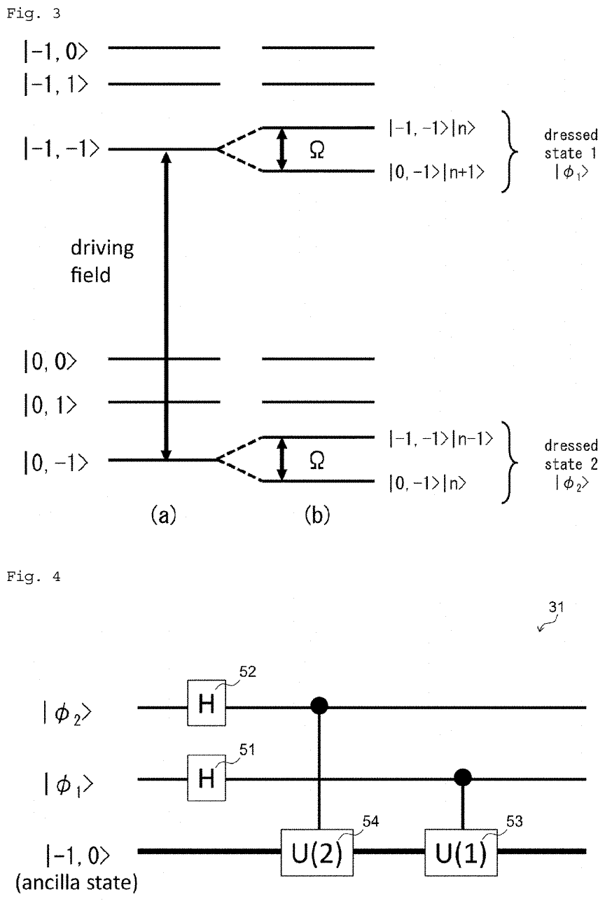

FIG. 3 is a view schematically showing the energy levels of an electron spin in an NV center before and after the generation of dressed states. (a) shows a state before the generation of dressed states, and (b) shows a state after the generation of dressed states. FIG. 2(b) shows a state in which magnetic field sensing is performed after the generation of dressed states.

When the NV center is irradiated with corresponding driving microwaves at a resonance frequency ω_{drive} between the ground state |0, −1> and excited state |−1, −1> of the NV center with its intensity Ω_{drive}, two dressed states |φ₁> and |φ₂> are generated in the electron spin state of the NV center. Specifically, when dressed states are generated for the two levels |−1, −1> and |0, −1>, four levels of |−1, −1>|n>, |0, −1>|n+1>, |−1, −1>|n−1>, and |0, −1>|n> are generated. Here, |n−1>, |n>, and |n+1> are the modes of driving microwaves, and n is a positive integer including 0 (0, 1, 2, . . . ). In this case, the split width between |−1, −1>|n−1> and |0, −1>|n>, and the split width Q between |−1, −1>|n> and |0, −1>|n+1> are equal to the intensity Ω_{drive} of the driving microwaves. That is, it is possible to operate between the two levels at the same time by microwaves at the same frequency as Ω_{drive}. This means that the two dressed-state levels are measured at the same time by one magnetic field sensing. The detailed procedure of magnetic field sensing is described later.

FIG. 2(c) shows a state of reading the phase information after the quantum operation.

After performing magnetic field sensing, the phase information of the two generated dressed states |φ₁> and |φ₂> is added by a quantum operation and detected. For addition by the quantum operation, a quantum circuit part described later is used. For the ancilla state used as an operation auxiliary in the quantum operation, for example, |−1, 0> is used in the present embodiment. Thereafter, for the state after addition by the quantum operation, the magnetic resonance signal between the ground state |0, −1> and excited state |−1, −1> of the NV center is detected as a change in luminescence intensity by optically detected magnetic resonance (ODMR). The change in luminescence intensity includes the phase information after the quantum operation.

FIG. 4 is a view schematically showing a quantum circuit part that performs a quantum operation on dressed states.

The quantum circuit part 31 comprises a first Hadamard action part 51, a second Hadamard action part 52, a first unitary action part 53, and a second unitary action part 54. In the present embodiment, the quantum circuit part 31 uses the state |−1, 0> for the ancilla state to assist the operation. To the ancilla state, an output after the action by the first unitary action part 53 and an output after the action by the second unitary action part 54 are added.

The first Hadamard action part 51 acts on the dressed state 1 |φ₁>. The first unitary action part 53 acts on the output of the first Hadamard action part 51 and adds the output to the ancilla state |−1, 0>. The second Hadamard action part 52 acts on the dressed state 2 |φ₂>. The second unitary action part 54 acts on the output of the second Hadamard action part 52 and adds the output to the ancilla state |−1, 0>. For example, in a quantum circuit implemented in quantum gates, the first Hadamard gate action part 51 and the second Hadamard gate action part 52 function as Hadamard gates, and the first unitary action part 53 and the second unitary action part 54 function as unitary operators (unitary gates).

The phase information added to the ancilla state is detected as a change in luminescence intensity by optically detected magnetic resonance (ODMR). The detected phase information is in a state corresponding to the physical quantity of the measurement target. Therefore, the physical quantity of the measurement target can be calculated by appropriately processing the detected phase information of the electron spin state after the interaction. The physical quantity of the measurement target can be calculated based on the electron spin Hamiltonian.

The electron spin Hamiltonian H_{gs} is represented by the following equation:

H_{gs}≅μ_{B}gₑS·B+hD_{gs}[S_{z}²−⅓S(S+1)]−d_{gs}^{⊥}└Eₓ(SₓS_{y}+S_{y}Sₓ)+E_{y}(Sₓ²−S_{y}²)┘

In this equation, μ_{B} is the Bohr magneton, gₑ is the g-factor of the electron, and h is Planck's constant. Vector S is the electron spin. Vector B is the applied magnetic field. D_{gs} is the zero magnetic field splitting constant. Sₓ, S_{y}, and S_{z} are x, y, and z direction components of electron spin S, respectively. d_{gs}^{⊥} is the electric dipole moment. Eₓ and E_{y} are x and y direction components of the electric field, respectively.

The First Term:

μ_{B}gₑS·B

is a term due to the Zeeman effect, and means that the electron spin functions as a magnetic field sensor.

The second and third terms are terms due to dipole interactions (i.e., inter-spin interactions). The second term:

hD_{gs}[S_{z}²−⅓S(S+1)]

means that the electron spin functions as a temperature sensor and a dynamic quantity (pressure) sensor. The third term:

−d_{gs}^{⊥}└Eₓ(SₓS_{y}+S_{y}Sₓ)+E_{y}(Sₓ²−S_{y}²)┘

means that the electron spin functions as an electric field sensor.

Accordingly, the strength of the magnetic field can be calculated based on the first term. The strength of the temperature and dynamic quantity can be calculated based on the second term. The strength of the electric field can be calculated based on the third term.

### Measurement Procedure

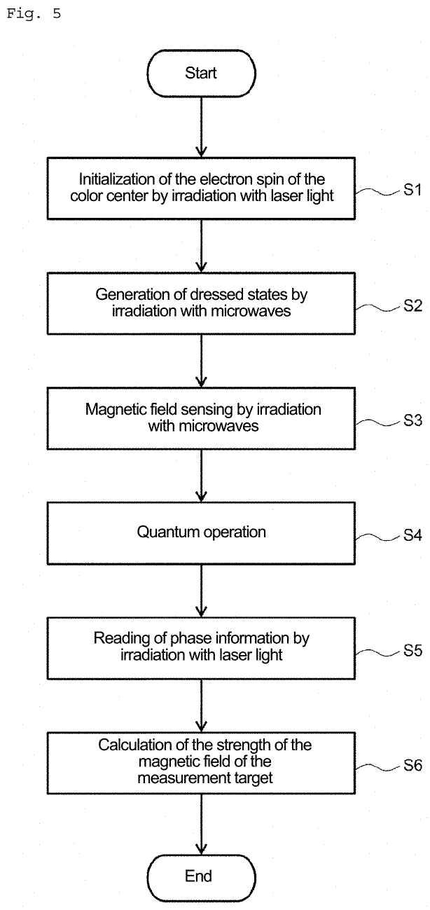

FIG. 5 is a flowchart showing the procedure of a measurement method according to one embodiment of the present invention.

In step S1, the electron spin of the color center (NV center) of the sensor element 1 is initialized by irradiating the sensor element 1 with laser light. Then, the initialized electron spin of the NV center is made to interact with the alternating magnetic field of the measurement target 9. After the interaction for a sufficient period of time, the electron spin state of the NV center becomes a state corresponding to the strength of the alternating magnetic field.

In step S2, a dressed state is generated in the electron spin state of the NV center by irradiating the sensor element 1 with driving microwaves. As a result, the electron spin state of the NV center of the sensor element 1 becomes a dressed state.

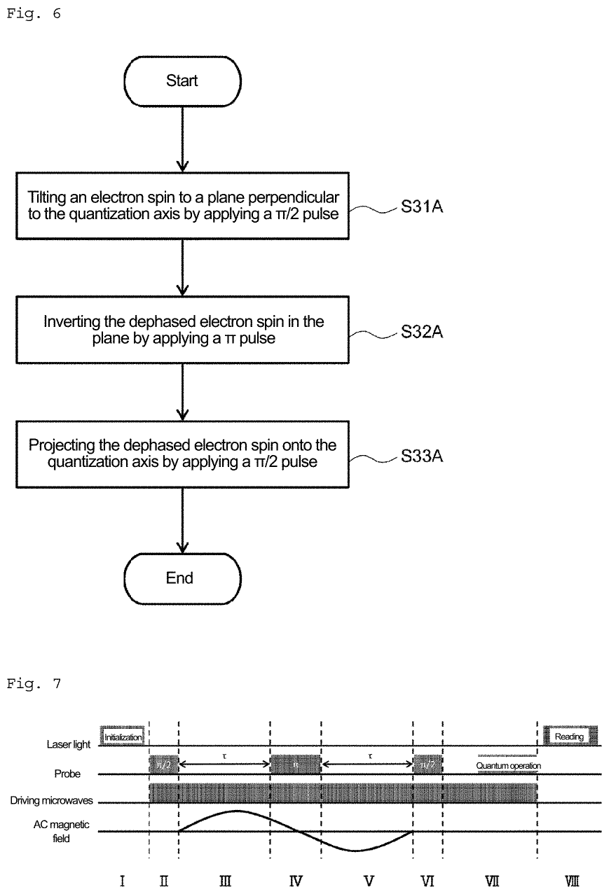

In step S3, magnetic field sensing is performed by irradiating the sensor element 1 with electromagnetic waves for spin operation. In the present embodiment, alternating magnetic field sensing is performed according to the procedure shown in steps S31A to S33A of FIG. 6.

### Alternating Magnetic Field Sensing

FIG. 6 is a flowchart showing the detailed procedure in the case of alternating magnetic field sensing. FIG. 7 is a pulse sequence for alternating magnetic field sensing. FIG. 8 is a view schematically showing the behavior of an electron spin corresponding to the pulse sequence of FIG. 7. In FIG. 8, the upper side shows the electron spin in the dressed state 1 |φ₁>, and the lower side shows the electron spin in the dressed state 2 |φ₂>.

State I corresponds to the state of step S1 and shows a state in which the electron spin is initialized by irradiation with laser light. The electron spin 7 is aligned in the direction along the z-axis, which is the quantization axis. State II corresponds to the state of step S2 and shows a state in which two dressed states are generated.

Next, in step S31A, an operation is carried out to tilt the electron spin along the quantization axis to a plane perpendicular to the quantization axis by applying a π/2 pulse. As shown in state II, the electron spin 7 is tilted to the x-y plane. Then, as shown in state III, the electron spin 7 tilted to the x-y plane is dephased by the interaction between the alternating magnetic field and the static magnetic field during a predetermined time τ. The time τ corresponds to the half wavelength of the alternating magnetic field of the measurement target.

After the elapse of a predetermined time τ, in step S32A, an operation is carried out to invert the electron spin, which is dephased by the interaction with the measurement target, in the plane by applying a π pulse. As shown in states III to IV, the position of the tip of the electron spin 7 is rotated in the x-y plane. In this case, as shown in state V, the reconvergence of the electron spin 7 cancels the static magnetic field component; however, the alternating magnetic field component is not canceled because the strength is reversed from state III.

After the elapse of a further predetermined time τ, in step S33A, an operation is carried out to project the dephased electron spin onto the quantization axis by applying a π/2 pulse. As shown in state VI, the electron spin 7 located within the x-y plane is projected onto the z-axis, which is the quantization axis, and is aligned in the direction along the z-axis.

State VII corresponds to the state of step S4 described later, and state VIII corresponds to the state of step S5 described later.

Reference is made again to FIG. 5 and FIG. 4. A quantum operation is performed in step S4 to thereby obtain phase information between multiple energy levels for the electron spin dressed state.

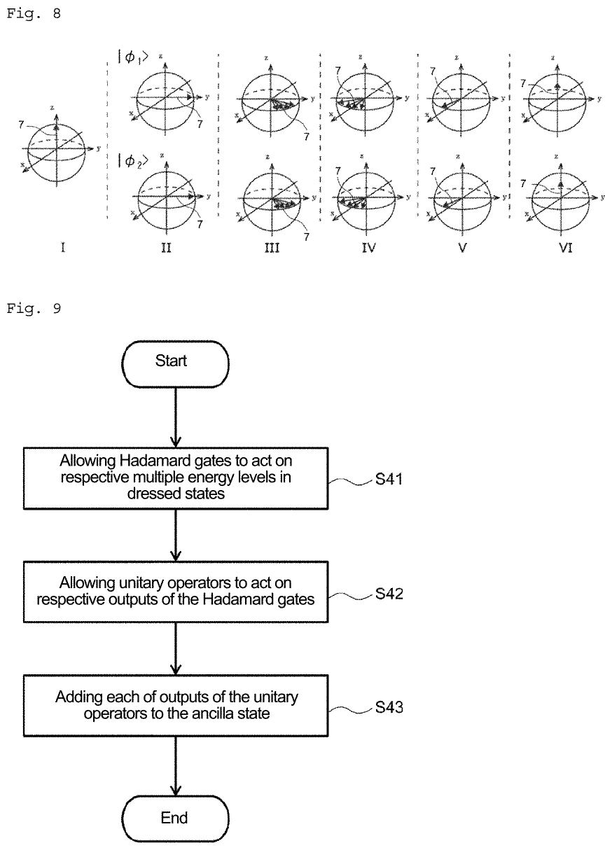

FIG. 9 is a flowchart showing the detailed procedure of the quantum operation.

In step S41, Hadamard gates are allowed to act on the respective multiple energy levels. The first Hadamard action part 51 is allowed to act on the dressed state 1 |φ₁>, and the second Hadamard action part 52 is allowed to act on the dressed state 2 |φ₂>.

$$\vert {ϕ}_{1} 〉 \to \frac{1}{\sqrt{2}} ( \vert 0 , - 1 〉 \vert n 〉 + \vert - 1 , - 1 〉 \vert n - 1 〉 )$$

$$\vert {ϕ}_{2} 〉 \to \frac{1}{\sqrt{2}} ( \vert 0 , - 1 〉 \vert n + 1 〉 + \vert - 1 , - 1 〉 \vert n 〉 )$$

In step S42, unitary operators are allowed to act on the outputs of the respective Hadamard gates. The first unitary action part 53 is allowed to act on the output of the first Hadamard action part 51, and the second unitary action part 54 is allowed to act on the output of the second Hadamard action part 52.

Then, in step S43, each of the outputs of the unitary operators is added to the quantum ancilla state. In the present embodiment, the phase information, which is the output from the two unitary action parts 53 and 54, is added to the ancilla state |−1, 0>, resulting in doubling the phase information.

$$\vert - 1 , 0 〉 \to {( \frac{1}{\sqrt{2}} )}^{2} exp ( \frac{2 π i}{{2}^{2}} 2 ) \vert {ϕ}_{1} 〉 \vert {ϕ}_{2} 〉 \vert - 1 , 0 〉 \qquad$$

Reference is made again to FIG. 5 and FIG. 2. In step S5, the phase information after the quantum operation is read by detecting a change generated in the sensor element 1 after irradiating the sensor element 1 with laser light. In the present embodiment, the phase information after the quantum operation is read for the electron spin state after the interaction by detecting the light emitted from the sensor element 1.

First, the phase information added and held in the ancilla state |−1, 0> is moved to the state |−1, −1> by using a π pulse. Next, the moved phase information held in the state |−1, −1> is detected by optically detected magnetic resonance (ODMR) as a change in luminescence intensity using the detection part 33.

The signal strength can be integrated to improve S/N by repeating the procedure shown in steps S1 to S5.

In step S6, the strength of the magnetic field of the measurement target is calculated. The phase information of the electron spin state after the interaction detected by the detection part 33 is in a state corresponding to the alternating magnetic field of the measurement target 9. Therefore, the strength of the alternating magnetic field can be calculated by appropriately processing the detected phase information of the electron spin state after the interaction. For example, the strength of the alternating magnetic field of the measurement target 9 can be calculated by determining the probability that the electron spin state after the interaction becomes the ground state. The strength is calculated based on the term due to the Zeeman effect of the electron spin Hamiltonian H_{gs}.

As described above, according to the first embodiment of the present invention, the decoherence time T₂ can be increased by generating dressed states in the electron spin state of the color center. This can reduce the minimum detectable strength Bₘᵢₙ of the alternating magnetic field, and improve the measurement sensitivity of the alternating magnetic field in measurement using a color center as a sensor.

Further, the measurement device 10 according to one embodiment of the present invention can operate at room temperature (about 300 K) without using a cooling mechanism. A superconducting quantum interference device (SQUID), which is known as an example of advanced highly sensitive magnetic field sensors, requires a cooling mechanism using, for example, liquid nitrogen in order to maintain the superconducting state. In contrast, the measurement device 10 according to one embodiment of the present invention does not need to comprise a cooling mechanism, and is thus more advantageous than other advanced magnetic field sensors in that it is easy to miniaturize the device and mount it on other devices (e.g., transportation equipment such as automobiles).

### Second Embodiment

As an example of the physical quantities of a measurement target, the second embodiment of the present invention describes a case of measuring the strength of the static magnetic field generated from the measurement target.

In the second embodiment, the detailed procedure of magnetic field sensing in step S3 is different from the procedure in the first embodiment. The other procedures are the same as those in the first embodiment.

### Static Magnetic Field Sensing

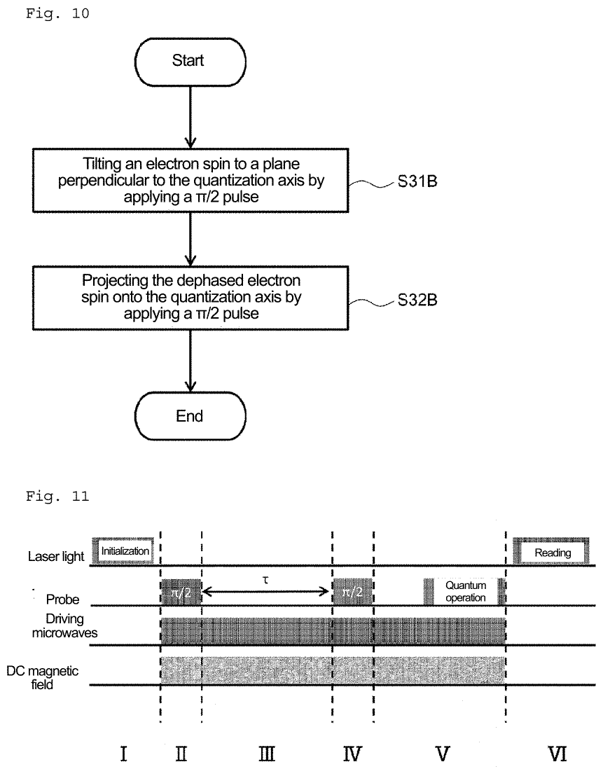

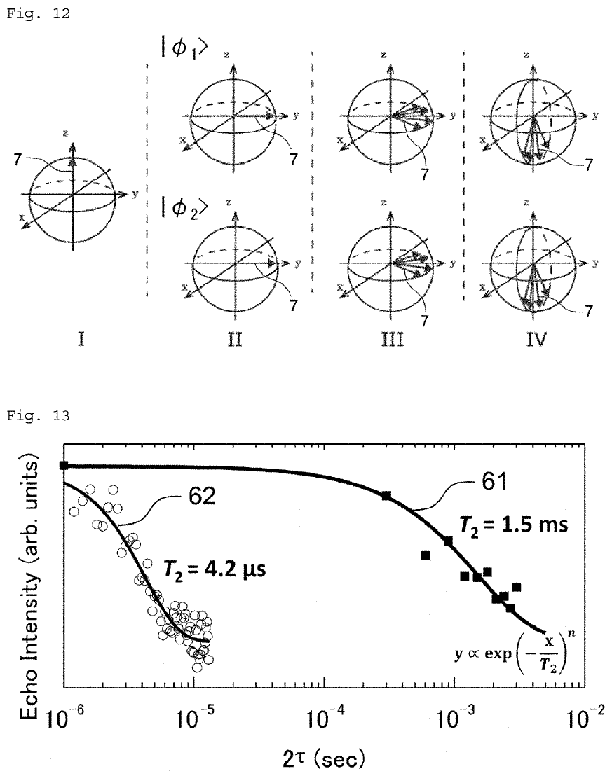

FIG. 10 is a flowchart showing the detailed procedure in the case of static magnetic field sensing. FIG. 11 shows a pulse sequence for static magnetic field sensing. FIG. 12 is a view schematically showing the behavior of an electron spin corresponding to the pulse sequence of FIG. 11. In FIG. 12, the upper side shows the electron spin in the dressed state 1 |φ₁>, and the lower side shows the electron spin in the dressed state 2 |φ₂>.

State I corresponds to the state of step S1 shown in the flowchart of FIG. 5, and shows a state in which the electron spin is initialized by irradiation with laser light. The electron spin 7 is aligned in the direction along the z-axis, which is the quantization axis. State II corresponds to the state of step S2 shown in the flowchart of FIG. 5, and shows a state in which two dressed states are generated.

Next, in step S31B, an operation is carried out to tilt the electron spin along the quantization axis to a plane perpendicular to the quantization axis by applying a π/2 pulse. As shown in state II, the electron spin 7 is tilted to the x-y plane. Then, as shown in state III, the electron spin 7 tilted to the x-y plane is dephased by interaction with the static magnetic field during a predetermined time τ.

After the elapse of a further predetermined time τ, in step S32B, an operation is carried out to project the dephased electron spin onto the quantization axis by applying a π/2 pulse. As shown in state IV, the electron spin 7 located within the x-y plane is projected onto the z-axis, which is the quantization axis, and is aligned in the direction along the z-axis.

State V corresponds to the state of step S4, and state VI corresponds to the state of step S5.

As described above, according to the second embodiment of the present invention, the measurement sensitivity of the static magnetic field can be improved in measurement using a color center as a sensor.

### Other Embodiments

Specific embodiments of the present invention are described above; however, the present invention is not limited to the above embodiments.

In the above embodiments, two dressed states |φ₁> and |φ₂> are generated; however, the number of dressed states to be generated is not limited to two, and a plurality of dressed states can be generated. For example, when three dressed states |φ₁>, |φ₂>, and |φ₃> are generated, the quantum circuit part 31 may comprise three Hadamard action parts and three unitary action parts, and the three dressed states |φ₁>, |φ₂>, and |φ₃> may be added together.

In the above embodiments, the physical quantity of the measurement target is a magnetic field (alternating magnetic field or static magnetic field); however, it is not limited to magnetic fields. Electric fields, temperatures, and dynamic quantities (e.g., dynamic stress and pressure) can be used as the physical quantities of the measurement target. These physical quantities are related to the interaction with the electron spin, and can be calculated based on the electron spin Hamiltonian.

In the above embodiments, an NV center is used as the diamond color center of the sensor element 1; however, usable color centers are not limited to NV centers. In place of NV centers, silicon-vacancy centers or germanium-vacancy centers may be used as the diamond color centers of the sensor element 1. Further, the color centers are also not limited to color centers of diamond crystals. Color centers of various crystals can be used for the sensor element 1 as long as dressed states can be generated in the electron spin state of the color center.

In the above embodiments, the magnetic resonance signal related to the electron spin state after the interaction is detected as a change in luminescence intensity by optically detected magnetic resonance (ODMR); however, the method of measuring the magnetic resonance signal is not limited thereto. For example, the magnetic resonance signal can be measured by known electrically detected magnetic resonance (EDMR). In electrically detected magnetic resonance (EDMR), photoexcitation of the sensor element 1, such as diamond color center, generates a spin state-dependent photocurrent. This photocurrent is generated by the difference in the lifetime of the excited state depending on the spin state. The detection part 33 detects the electrical resistance of the sensor element 1 (or photocurrent generated in the sensor element 1), thereby detecting the magnetic resonance signal as a change in electrical resistivity (or a change in photocurrent due to light irradiation). That is, the detection part 33 functions as an electrical detection part. For example, a known ammeter can be used as the detection part 33.

Moreover, in the pulse sequence for static magnetic field sensing shown in FIG. 11, the direct-current magnetic field may be applied to the sensor element 1 at least in the section corresponding to state III.

### EXAMPLES

Examples of the present invention are shown below to further clarify the features of the present invention.

### Example 1

In Example 1, the magnetic resonance signal intensity was measured for an NV⁻ dressed electron spin based on the measurement method according to the first embodiment using a pulse sequence for measuring an alternating magnetic field. Further, the decoherence time T₂ of the dressed electron spin was determined from the signal intensity obtained by the measurement.

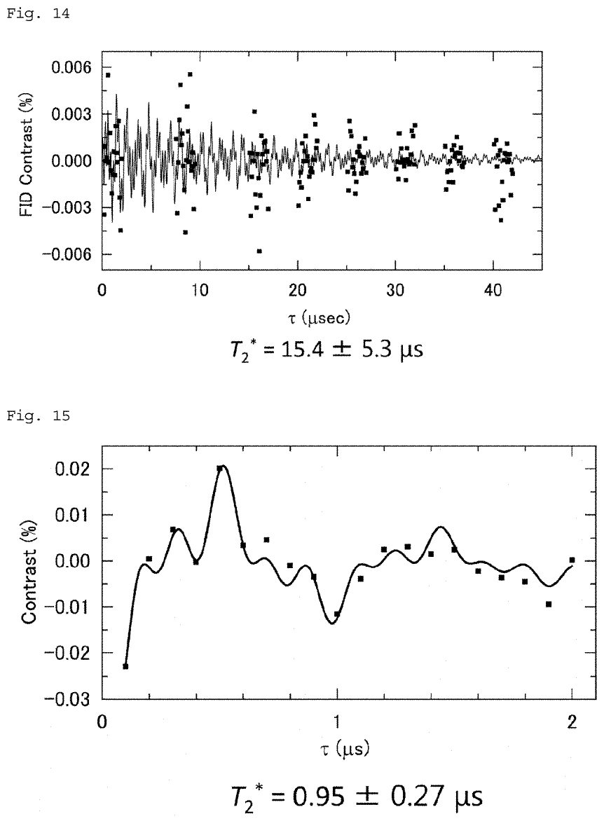

FIG. 13 is a graph showing the results of measuring the decoherence time T₂ in Example 1. The vertical axis of the graph corresponds to the intensity (echo intensity) of the magnetic resonance signal. For comparison, the graph also shows the results of measuring the decoherence time T₂ of an NV⁻ bare electron spin (i.e., undressed). In the graph, the measured values of the magnetic resonance signal intensity for the dressed electron spin are indicated by square symbols, and the fitting line of these measured values is indicated by sign 61. Similarly, the measured values of the magnetic resonance signal intensity from the bare electron spin are indicated by circle symbols, and the fitting line of these measured values is indicated by sign 62.

As a result of the measurement, the decoherence time T₂ of the dressed electron spin was about 1.5 ms, and the decoherence time T₂ of the bear electron spin was about 4.2 μs. According to the measurement results in Example 1, the generation of dressed states in the NV⁻ electron spin increased the decoherence time T₂ 100-fold or more (about 350-fold).

As the decoherence time T₂ increases, the minimum detectable strength Bₘᵢₙ of the magnetic field decreases, and the detection sensitivity is improved. Therefore, it was indicated that in the measurement of the alternating magnetic field, the generation of dressed states in the NV⁻ electron spin reduced the minimum detectable strength Bₘᵢₙ of the magnetic field, and improved the detection sensitivity in the magnetic field measurement by a sensor using color centers in diamond.

### Example 2

In Example 2, the magnetic resonance signal intensity was measured for an NV⁻ dressed electron spin based on the measurement method according to the second embodiment using a pulse sequence for measuring a static magnetic field. As distinguished from the decoherence time T₂ determined by the echo method, the decoherence time in this case is referred to as “T₂*.” The decoherence time T₂* of the dressed electron spin was determined from the signal intensity obtained by the measurement. The output of the laser light used for the measurement was about 100 μW, the pulse width of the laser light was about 10 μs, and the pulse width of the π pulse was about 42 ns.

FIG. 14 is a graph showing the results of measuring the decoherence time T₂* of the dressed electron spin in Example 2. In the graph, the measured values of the magnetic resonance signal intensity are indicated by square symbols, and the fitting line of these measured values is indicated by a solid line. As a result of the measurement, the decoherence time T₂* of the dressed electron spin was 15.4±5.3 μs.

Further, for comparison, the magnetic resonance signal intensity was measured for an NV⁻ bear electron spin. The decoherence time T₂* of the bear electron spin was determined from the signal intensity obtained by the measurement. The output of the laser light used for the measurement was about 100 μW, the pulse width of the laser light was about 10 μs, and the pulse width of the π pulse was about 44 ns.

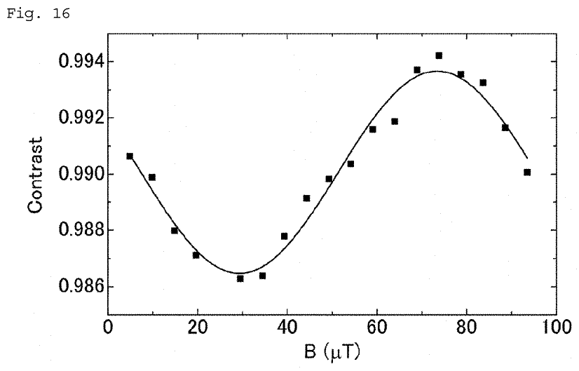

FIG. 15 is a graph showing the results of measuring the decoherence time T₂* of the bear electron spin in Example 2. In the graph, the measured values of the magnetic resonance signal intensity are indicated by square symbols, and the fitting line of these measured values is indicated by a solid line. As a result of the measurement, the decoherence time T₂* of the bear electron spin was 0.95±0.27 μs.

As shown in the measurement results of FIGS. 14 and 15, the generation of dressed states in the NV⁻ electron spin increased the decoherence time T₂* about 15-fold. Therefore, it was indicated that in the measurement of the static magnetic field, the generation of dressed states in the NV⁻ electron spin improved the detection sensitivity.

### Example 3

In Example 3, in the case of measuring a static magnetic field, the detection sensitivity was compared between when dressed states were generated in the electron spin and when no dressed state was generated in the electron spin (in a bear state). The magnetic resonance signal intensity was measured under the same conditions as in Example 2. The time τ between π/2 pulses in the pulse sequence was 25 μs.

FIG. 16 is a graph showing the correspondence relationship between the magnetic resonance signal intensity and the static magnetic field of the measurement target in Example 3. The graph of FIG. 16 was obtained by changing the magnitude of the static magnetic field of the measurement target. In the graph, the measured values of the magnetic resonance signal intensity are indicated by square symbols, and the fitting line of these measured values is indicated by a solid line. The detection sensitivity was calculated based on the slope of the fitting line in the graph of FIG. 16 and the standard deviation σ of the measured values of the magnetic resonance signal intensity shown on the vertical axis of the graph. Further, a graph similar to FIG. 16 was also created for a case in which no dressed state was generated in the electron spin, and the detection sensitivity was calculated from the created graph. The results of calculating the detection sensitivity are shown in Table 1.

TABLE 1

| State | τ (μs) | Sensitivity (T/√Hz) | Ratio |
|---|---|---|---|
| Bare | 1.5 | 1.77 × 10⁻⁴ | 1.0 |
| Dressed | 25 | 5.79 × 10⁻⁵ | 3.1 |

As shown in the calculation results of Table 1, the generation of dressed states in the NV⁻ electron spin increased the detection sensitivity about 3.1-fold. Therefore, it was confirmed that in the measurement of the static magnetic field, the generation of dressed states in the NV⁻ electron spin improved the detection sensitivity.

### REFERENCE SIGNS LIST

1. Sensor element
2. Irradiation unit
3. Physical quantity measuring unit
7. Electron spin
8. Interaction
9. Measurement target
10. Measurement device
11. Probe
21. Driving microwave irradiation part
22. Operation electromagnetic wave irradiation part
31. Quantum circuit part
32. Light irradiation part
33. Detection part
34. Data processing part
51, 52. Hadamard action parts
53, 54. Unitary action parts
99. Network

1. A sensor element having a color center in a diamond crystal structure, wherein the electron spin state of the color center is a dressed state.

2. The sensor element according to claim 1, wherein the color center is a diamond complex containing nitrogen (N) replacing one carbon atom and a vacancy (V) adjacent to the nitrogen.

3. A measurement device comprising:
an irradiation unit that irradiates a sensor element having a color center with driving microwaves for generating a dressed state in the electron spin state of the color center that changes due to interaction with a measurement target, and with operation electromagnetic waves for operating the electron spin state; and
a physical quantity measuring unit that calculates a physical quantity of the measurement target based on the electron spin dressed state after the interaction with the measurement target.

4. The measurement device according to claim 3, wherein the physical quantity measuring unit comprises:
a quantum circuit part that performs a quantum operation on phase information between multiple energy levels for the electron spin dressed state after the interaction with the measurement target;
a light irradiation part that irradiates the sensor element with light for reading the phase information after the quantum operation;
a detection part that detects a change generated in the sensor element due to the irradiation of the light; and
a data processing part that reads the phase information after the quantum operation from the detected change and calculates the physical quantity based on the read phase information.

5. The measurement device according to claim 4, wherein the quantum circuit part comprises:
a plurality of Hadamard action parts that act on the respective multiple energy levels; and
a plurality of unitary action parts that act on respective outputs of the plurality of Hadamard action parts and add the outputs to a quantum ancilla state.

6. The measurement device according to claim 3, wherein the color center is a complex of nitrogen (N) replacing a carbon atom and a vacancy (V) adjacent to the nitrogen.

7. The measurement device according to claim 3, wherein the physical quantity measuring unit calculates at least one of a magnetic field, an electric field, a temperature, and a dynamic quantity as the physical quantity related to interaction with the electron spin.

8. A measurement method comprising the steps of:
irradiating a sensor element having a color center with driving microwaves for generating a dressed state in the electron spin state of the color center that changes due to interaction with a measurement target;
irradiating the sensor element with operation electromagnetic waves for operating the electron spin state; and
calculating a physical quantity of the measurement target based on the electron spin dressed state after the interaction with the measurement target.

9. The measurement method according to claim 8, wherein the step of calculating the physical quantity comprises:
performing a quantum operation on phase information between multiple energy levels for the electron spin dressed state;
irradiating the sensor element with light for reading the phase information after the quantum operation;
detecting a change generated in the sensor element due to the irradiation of the light; and
reading the phase information after the quantum operation from the detected change and calculating the physical quantity based on the read phase information.

10. The measurement method according to claim 9, wherein the step of performing a quantum operation comprises:
allowing Hadamard gates to act on the respective multiple energy levels; and
allowing unitary operators to act on respective outputs of the Hadamard gates, and adding each of outputs of the unitary operators to a quantum ancilla state.

11. The measurement method according to claim 8, wherein the step of applying operation electromagnetic waves comprises:
applying a π/2 pulse to thereby tilt an electron spin along a quantization axis to a plane perpendicular to the quantization axis;
applying a π pulse to thereby invert the electron spin dephased by the interaction with the measurement target in the plane; and
applying a π/2 pulse to thereby project the dephased electron spin onto the quantization axis.

12. The measurement method according to claim 8, wherein the step of applying operation electromagnetic waves comprises:
applying a π/2 pulse to thereby tilt an electron spin along a quantization axis to a plane perpendicular to the quantization axis; and
applying a π/2 pulse to thereby project the electron spin dephased by the interaction with the measurement target onto the quantization axis.
